(19) United States
(12) Patent Application Publication
(10) Pub. No.: US 2023/0234160 A1
(43) Pub. Date: Jul. 27, 2023

(54) DIFFUSION BONDING OF PURE METAL BODIES

(71) Applicant: Applied Materials, Inc., Santa Clara, CA (US)

(72) Inventors: Joseph Frederick Behnke, San Jose, CA (US); Joseph Frederick Sommers, Roseville, CA (US)

(21) Appl. No.: 18/157,714

(22) Filed: Jan. 20, 2023

Related U.S. Application Data
(60) Provisional application No. 63/302,499, filed on Jan. 24, 2022.

(51) Int. Cl. B23K 20/02; H01J 37/32

(52) U.S. Cl. CPC B23K 20/026; H01J 37/32816; H01J 37/32522; H01J 2237/332

(57) ABSTRACT

A method includes applying a bond layer of a first chemical composition to a first surface of a first metal body. The metal body is of a second chemical composition. The method further includes disposing a second metal body of the second chemical composition against the first metal body such that the bond layer is between the first surface of the first metal body and a second surface of the second metal body. The metal bodies are resistant to diffusion bonding. The bond layer facilitates diffusion bonding of the metal bodies. The method further includes heating the first metal body and the second metal body. The method further includes applying pressure to press the second metal body against the first metal body. The method further includes generating a diffusion bond between the metal bodies, responsive to the heating and the applying of pressure for a duration.

### RELATED APPLICATION

This application claims the benefit of U.S. Provisional Application No. 63/302,499, filed Jan. 24, 2022, the content of which is hereby incorporated by reference in its entirety.

### TECHNICAL FIELD

Embodiments of the present disclosure relate to forming articles using diffusion bonding. More specifically, embodiments of the present disclosure relate to forming articles from pure metal bodies using diffusion bonding.

### BACKGROUND

In manufacturing and processing systems (e.g., processing chambers), conditions proximate to a work piece (e.g., a substrate, a semiconductor wafer, etc.) determine the result of the processing. Conditions are controlled by components of the processing system. In some applications, substrates are to be processed in hostile environments, e.g., high temperatures, corrosive environments (e.g., plasma environments, fluorine gas environments), high electrical voltages, etc. Processes may be sensitive to the materials chosen to construct components of the processing equipment. For example, aluminum may not be suitable for a high temperature environment. In some cases, small amounts of contaminants (e.g., alloying agents) in the material of a component may leech into the substrate and cause unanticipated or unacceptable performance.

In some cases, a component is to have a complex geometry. Components of complex geometry, in particular complex internal geometry, may be inconvenient, difficult, or impossible to machine. Diffusion bonding is one method of constructing components with a complex internal geometry. Diffusion bonding utilizes a concentration gradient (e.g., of two different metals) to drive the exchange of atoms between two metal bodies to join them together into one solid object or article. Diffusion bonding does not generally work for bonding two pure metal bodies that are composed of the same metal.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the present disclosure, a method disclosed includes applying a bond layer of a first chemical composition to a first surface of a first metal body. The metal body is of a second chemical composition. The second chemical composition is different from the first chemical composition. The method further includes disposing a second metal body of the second chemical composition against the first metal body such that the bond layer is between the first surface of the first metal body and a second surface of the second metal body. The first metal body and the second metal body are resistant to diffusion bonding. The bond layer facilitates diffusion bonding of the second metal body to the first metal body. The method further includes heating the first metal body and the second metal body. The method further includes applying pressure to press the second metal body against the first metal body. The method further includes generating a diffusion bond between the second metal body and the first metal body, responsive to the heating and the applying of pressure for a duration.

In another aspect of the present disclosure, a chamber component for a processing chamber is disclosed. The chamber component includes a first substantially pure metal body. The first body is composed of a first chemical composition. The chamber component further includes a second substantially pure metal body. The second body is composed of the first chemical composition. The first chemical composition is resistant to diffusion bonding. The chamber component further includes a diffusion bond between a first surface of the first metal body and a second surface of the second metal body, wherein the diffusion bond comprises a spatial gradient of the first chemical composition and a second chemical composition of a bond layer from the first metal body through the bond layer to the second metal body.

In another aspect of the present disclosure, a processing chamber is disclosed. The processing chamber includes a showerhead. The showerhead includes a first substantially pure metal body, of a first chemical composition. The showerhead includes a second substantially pure metal body, of the first chemical composition. The first chemical composition is resistant to diffusion bonding. The showerhead further includes a diffusion bond between a first surface of the first metal body and a second surface of the second metal body. The diffusion bond is composed of a spatial gradient of the first chemical composition and a second chemical composition of a bond layer from the first metal body through the bond layer to the second metal body.

### BRIEF DESCRIPTION OF THE DRAWINGS

Embodiments of the present invention are illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of a processing chamber having one or more chamber components that may be manufactured of substantially pure metal by diffusion bonding, according to some embodiments.

FIG. 2 depicts a diffusion bonding system that includes a sectional view of a diffusion bonding chamber, according to some embodiments.

FIG. 3 depicts an exemplary architecture of a deposition system for performing aerosol deposition, according to some embodiments.

FIGS. 4A-B depict a mechanism and apparatus for performing deposition techniques utilizing energetic particles, according to some embodiments.

FIG. 5 depicts a schematic drawing of a plasma spray deposition apparatus used for spray deposition techniques, according to some embodiments.

FIG. 6 depicts a schematic drawing of an electroplating system for applying a bonding layer coating, according to some embodiments.

FIG. 7 is a flow diagram of a method for manufacturing a diffusion-bonded article composed of substantially pure metal, according to some embodiments.

FIGS. 8A-B depict sectionals view of an exemplary article formed of substantially pure metal bodies using diffusion bonding, according to some embodiments.

### DETAILED DESCRIPTION OF EMBODIMENTS

Described herein are technologies related to improved methods of fabrication of components for process chambers. In particular, improved methods to fabricate pure metal components of process chambers by diffusion bonding, such as those that may be used as components of processing equipment for semiconductor processing, are disclosed. Components of processing equipment may include internal structure such as channels, openings, etc. The properties (e.g., dimensions, including internal dimensions) of components impact conditions proximate to a product being produced by the processing equipment. The conditions proximate to the work piece determine the properties of the finished product. For example, a processing chamber may be used to process a substrate, such as a semiconductor wafer. The properties of components of the processing chamber impact processing conditions experienced by the substrate. The proximate conditions determine performance of the product (e.g., whether the final product exhibits target property values).

In some embodiments, a target processing component (e.g., target geometry) may be inconvenient or impossible to machine from a solid piece of raw material, such as a component with complex internal structure. In some conventional systems, compromises may be made to achieve feasibility of construction, such as designing a component with machinable structure or utilizing multiple pieces clamped, glued, or otherwise bonded together.

Some manufacturing processes are sensitive to contaminants. For such a manufacturing process, the materials that components are constructed from may be chosen to avoid materials that may contaminate the target product. For example, some materials may leech out of processing components and negatively impact performance of a semiconductor wafer. Multi-piece components held together by a bonding agent may be affected by this sensitivity to contaminants because many bonding agents include materials that may contaminate a manufacturing process.

Diffusion bonding is a joining technique that operates on the principle of solid-state diffusion. Under certain conditions, the atoms of two solid metallic surfaces intersperse themselves over time. Diffusion bonding may be implemented by applying high pressure to two metallic bodies, in a high temperature environment. Atoms of the two bodies are exchanged over time until the interface between the two articles disappears and one article is formed.

Diffusion bonding is driven by a global (e.g., two unlike metals) or local (e.g., two unlike local environments) concentration of material. Unlike metals are often good candidates for diffusion bonding. Alloys are able to be joined in diffusion bonds as well due to the fact that alloys include multiple constituent materials. However, in some applications a target component is to be constructed of a pure metal without contaminant materials. In such applications, the metal bodies are resistant to diffusion bonding and diffusion bonding is not viable.

Aspects of the present disclosure address at least some of these deficiencies of conventional methods. Disclosed herein are chamber components and techniques for making the chamber components of pure metals via diffusion bonding. Embodiments enable bodies of a single pure metal composition and/or complicated internal structure to be manufactured. The bodies may be free of contaminating materials. In some embodiments, a thin layer of a second material is placed between the bodies of pure metal, wherein the second material is different than the material of the pure bodies. Diffusion bonding procedures are then employed. A concentration gradient between the pure materials and the second material drives the exchange of atoms between the materials. The diffusion bonded article may not have a distinct bonding layer, unlike braised or otherwise glued articles. Instead, the diffusion bonded article may exhibit a concentration gradient from pure metal to a region where the second material has diffused into the pure metal, generating a mixed material (e.g., alloy) at a region between the two metal bodies and back to pure metal.

In some aspects of the present disclosure, a method includes shaping a first substantially pure metal body. The first substantially pure metal body comprises a first chemical composition. The method further includes shaping a second substantially pure metal body, comprising the first chemical composition. The method further includes applying a bond layer comprising a second chemical composition to a first surface of the first metal body, wherein the second chemical composition is different from the first chemical composition. The method further includes arranging the metal bodies such that the bond layer is between the first surface of the first metal body and a second surface of the second metal body. The method further includes generating a diffusion bond between the first metal body and the second metal body by applying a pressure and temperature for a duration to bond the first body and the second body.

In another aspect of the present disclosure, a chamber component for a processing chamber is disclosed. The chamber component includes a first substantially pure metal body, comprising a first chemical composition. The chamber component further includes a second substantially pure metal body, comprising the first chemical composition. The chamber component further includes a diffusion bond between a first surface of the first metal body and a second surface of the second metal body. The diffusion bond comprises a spatial gradient of the first chemical composition and a second chemical composition of a bond layer from the first metal body through the bond layer to the second metal body. The second chemical composition may be different than the first chemical composition. For example, the first chemical composition may be a pure metal, and the second chemical composition may be an alloy of the pure metal. The chemical composition of the chamber component then comprises a spatial gradient from the first metal body through the bond layer to the second metal body.

In another aspect of the present disclosure, a processing chamber is disclosed. The processing chamber includes a showerhead. The showerhead includes a first substantially pure metal body, of a first chemical composition. The showerhead includes a second substantially pure metal body, of the first chemical composition. The first chemical composition is resistant to diffusion bonding. The showerhead further includes a diffusion bond between a first surface of the first metal body and a second surface of the second metal body. The diffusion bond is composed of a spatial gradient of the first chemical composition and a second chemical composition of a bond layer from the first metal body through the bond layer to the second metal body.

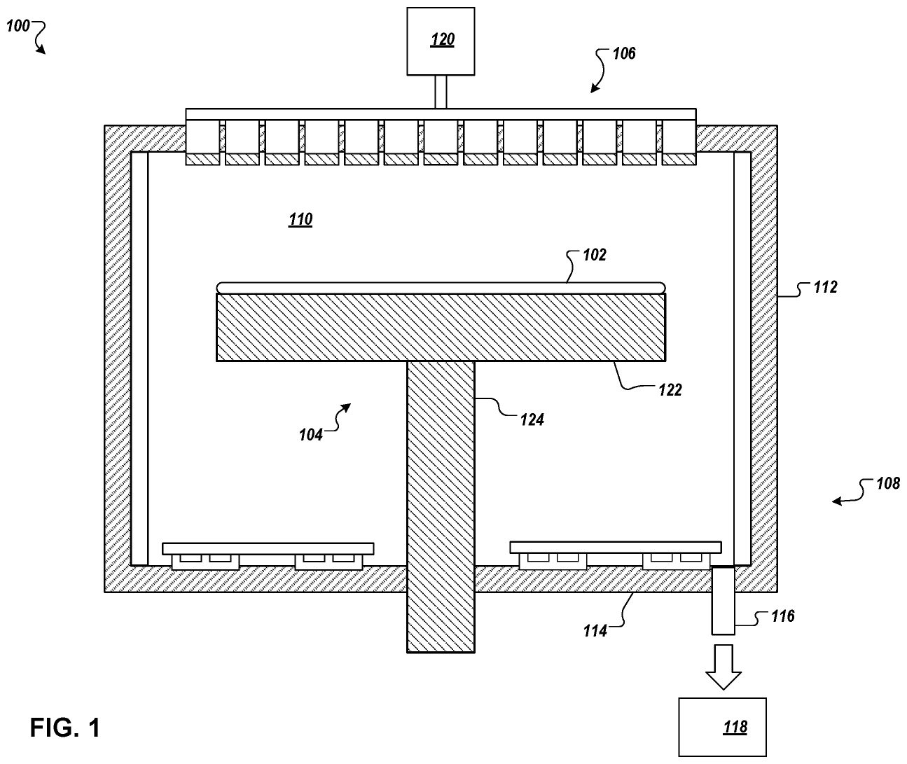

FIG. 1 depicts a sectional view of a processing chamber 100 having one or more chamber components that may be manufactured of substantially pure metal by diffusion bonding, according to some embodiments. Processing chamber 100 may include components with complex internal structures (e.g., internal structures that may not be able to be machined from a solid block) such as a showerhead. Processing chamber 100 may be used for processes in which a corrosive plasma environment having plasma processing conditions is provided. For example, the processing chamber 100 may be a chamber for a plasma etcher or plasma etch reactor, a plasma cleaner, and so forth. Processing chamber 100 may be used for processes sensitive to contamination, such as semiconductor wafer processing. Examples of chamber components that may be a part of processing chamber 100 include a substrate support assembly 104, an electrostatic chuck (ESC), a ring (e.g., a process kit ring or single ring), a chamber wall, a base, a gas distribution plate, a showerhead 106, a nozzle, a lid, a liner, a liner kit, a shield, a plasma screen, a flow equalizer, a cooling base, a chamber viewport, a chamber lid, and so on.

In one embodiment, processing chamber 100 includes a chamber body 108 and a showerhead 106 that enclose an interior volume 110. The showerhead may include a showerhead base and a showerhead gas distribution plate. Alternatively, the showerhead 106 may be replaced by a lid and a nozzle in some embodiments. The chamber body 108 may be fabricated from aluminum, stainless steel, nickel, or other suitable material. The chamber body 108 generally includes sidewalls 112 and a bottom 114. Any of the showerhead 106 (or lid and/or nozzle), sidewalls 112 and/or bottom 114 may include an arcing and/or plasma resistant coating layer.

An exhaust port 116 may be defined in the chamber body 108, and may couple the interior volume 110 to a pump system 118. The pump system 118 may include one or more pumps and throttle valves utilized to evacuate and regulate the pressure of the interior volume 110 of processing chamber 100.

Showerhead 106 may be supported on the sidewall 112 of the chamber body 108. The showerhead 106 (or lid) may be opened to allow access to the interior volume 110 of processing chamber 100, and may provide a seal for processing chamber 100 while closed. A gas panel 120 may be coupled to processing chamber 100 to provide process and/or cleaning gases to the interior volume 110 through showerhead 106 or lid and nozzle. Showerhead 106 is used for processing chambers used for dielectric etch (etching of dielectric materials). The showerhead 106 includes a gas distribution plate (GDP) having multiple gas delivery holes throughout the GDP. Showerhead 106 is an example of a component that may be fabricated using diffusion bonding techniques described in this disclosure. Showerhead 106 may include complex interior structure. Showerhead 106 may be composed of a substantially pure metal. In some embodiments, “substantially pure” indicates a metal with a purity of at least 99.9%. In some embodiments, the material used to fabricate a component using diffusion bonding (e.g., showerhead 106) may be at least 99.99% pure. In some embodiments, the material used to fabricate a component using diffusion bonding may be at least 99.999% pure. In some embodiments, showerhead 106 may be composed of substantially pure nickel.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃-ZrO₂. The nozzle may also be a ceramic, such as Y₂O₃, YAG, or the ceramic compound comprising Y₄Al₂O₉ and a solid-solution of Y₂O₃-ZrO₂. The lid, showerhead base, GDP and/or nozzle may be coated with an arcing and/or plasma resistant coating layer.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 104 is disposed in the interior volume 110 of the processing chamber 100 below the showerhead 106 or lid. The substrate support assembly 104 holds the substrate 102 during processing. A ring (e.g., a single ring) may cover a portion of the support assembly 104 (e.g., susceptor 122), and may protect the covered portion from exposure to plasma during processing. The ring may be silicon or quartz in one embodiment. Substrate support assembly 104 may include a pedestal 124, and a susceptor 122.

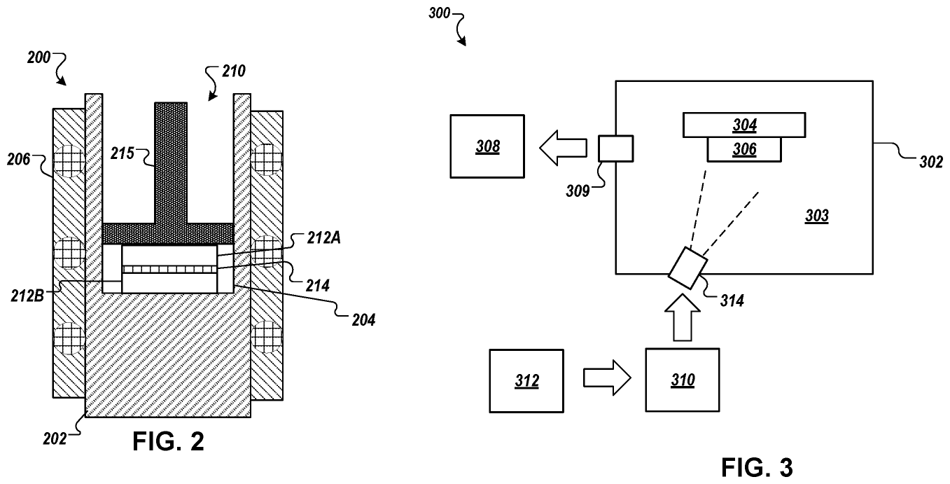

FIG. 2 depicts diffusion bonding system 200 that includes a sectional view of a diffusion bonding chamber 202 according to some embodiments. Diffusion bonding system 200 may be configured to perform diffusion bonding of two bodies comprised of substantially pure metal, such as substantially pure (e.g., 99.9% purity or greater) nickel.

Diffusion bonding system 200 includes diffusion bonding chamber 202 having an interior 204 surrounded by walls and a bottom. In some embodiments, interior 204 may be a sealed chamber capable of maintaining low or high pressure conditions, or may be capable of processing an article in an environment of inert gas, and may be coupled to appropriate gas flow sources. In some embodiments, the diffusion bonding chamber 202 includes a furnace 206, which may enclose diffusion bonding chamber 202, for example, in a cylindrical fashion. The furnace 206 may be programmable, and include one or more temperature sensors disposed within the hot pressing chamber 202 to provide feedback utilized to maintain a target temperature. The gas flow system may also be programmable, and diffusion bonding chamber 202 may include one or more pressure sensors. The furnace 206 may also be capable of ramping to a target temperature at a target rate. In some embodiments, the furnace 206 may be operatively coupled to a computing device. The computing device may run one or many stored recipes (which may be pre-defined or operator-defined) that control the conditions of the furnace 206, the gas flow system, etc. Diffusion bonding chamber 202 may maintain an elevated temperature while performing diffusion bonding of bodies 212A-B. In some embodiments, the temperature may be between 50% and 90% the absolute melting temperature of the material composing the first and second bodies. In some embodiments, the temperature may be between 60% and 80% of the absolute melting temperature of the material composing the first and second bodies. In some embodiments, the temperature may be about 70% of the absolute melting temperature of the material composing the first and second bodies. In some embodiments, nickel may be diffusion bonded between 1000° F. and 2300° F., between 1400° F. and 2000° F., at about 1700° F., or any subrange of these values. As used here, “about” indicates a range near the indicated value, for instance the value +/−10%.

Diffusion bonding chamber 202 may include an opening 210. One or more bodies 212A-B on which a bonding layer 214 has been formed may be inserted into diffusion bonding chamber 202. Methods of depositing a bonding layer 214 are discussed in more detail in FIGS. 3-6. A press 215 may then apply pressure to compress the bodies 212A-B together. Press 215 (also referred to as a punch) applies pressure while the furnace 206 heats the bodies 212A-B and bonding layer 214. Note that only a single upper press 215 is shown. However, in embodiments a lower press may also be used that presses in an opposite direction from the upper press 215. In some embodiments, pressure is applied to the metal bodies to reduce the overall thickness of the bodies by 0.1% to 5%. In some embodiments, pressure is applied to the metal bodies to reduce the overall thickness of the bodies by about 1%. The heat and pressure cause the bonding layer 214 and the pure metal bodies 212A-B to form a single diffusion bonded article, such as a component for a processing chamber. In some embodiments, the heat and pressure are maintained for several hours. In some embodiments, the heat and pressure are maintained for at least 5 hours. In some embodiments, the heat and pressure are maintained for at least 10 hours. In some embodiments, the heat and pressure are maintained for about 24 hours.

In some embodiments, conventional techniques are not suitable for fabricating a chamber component. In some conventional systems, a component with complex internal structure may be manufactured using a braising technique. Braising includes placing a thin foil of a material with a lower melting point between two bodies, and heating the assembly to melt the foil and bond the two bodies together. Such a technique may not be applicable in cases where the component is to be used in a high-temperature application, in particular if the intended use of the component involves temperatures high enough to melt (or weaken) the bonding material. In a diffusion bonding system, such as system 200, the material used as bonding layer 214 may be a material suitable for high temperature environments. In some embodiments, the material used as bonding layer 214 may have a higher melting temperature than the material of bodies 212A-B. Additionally, braising material often contaminates inner structures of a piece. Braising materials often do not possess high corrosion resistance.

In some embodiments, bodies 212A-B may be composed of substantially pure material (e.g., of the same substantially pure material). In some embodiments, bodies 212A-B may be composed of substantially pure nickel. Bonding layer 214 may be composed of a metal, an alloy, a non-metal, etc., to generate a concentration gradient for driving diffusion and eliminate interfaces between layers of the diffusion bonded article. In some embodiments, bonding layer 214 may be composed of a material such that atoms of the material may replace atoms in a lattice comprising bodies 212A-B. For example, body 212A and body 212B may each be composed of pure nickel, and the material of bonding layer 214 may be chosen such that atoms may exchange between the material of the bodies 212A-B and the material of bonding layer 214. Atoms diffused from bonding layer 214 may occupy lattice positions of bodies 212A-B, e.g., via substitutional diffusion bonding. Gold and copper are examples of materials that may replace nickel atoms in a nickel lattice, for example. The material of bonding layer 214 may be chosen such that the material interrupts the lattice structure of body 212A-B, e.g., via interstitial diffusion bonding. For example, materials such as aluminum, boron, or titanium may diffusion bond with nickel by diffusing and eliminating boundaries between layers such that the bonding material interrupts a nickel atom lattice. The material of bonding layer 214 may be chosen to drive diffusion by introducing a concentration gradient by using an alloy. For example, bodies 212A-B may be composed of substantially pure nickel, and bonding layer 214 may be composed of a nickel alloy. In some embodiments, bonding layer 214 may contain phosphorus. In some embodiments, bonding layer 214 may be electroless nickel plating. Bonding layer 214 may be a thin layer of material. In some embodiments, the bonding layer deposited may be less than 10 μm, less than 5 μm, or less than 1 μm thick. Atoms of the bonding layer 214 may migrate (e.g., diffuse) into bodies 212A-B during diffusion bonding, and atoms of bodies 212A-B may migrate into the bonding layer 214. The completed article may have no boundaries between layers, rather a gradient of concentration of material from a region of substantially pure metal in a first body to a region of mixed materials and back to a region of pure metal in a second body.

Bonding layer 214 may be applied to a surface of a body 212A and/or 212B using any method suitable for depositing a layer of a material on a surface, including electroplating, vapor deposition (e.g., physical vapor deposition, such as sputtering or evaporation, chemical vapor deposition, such as atomic layer deposition, etc.), ion assisted deposition, plasma deposition, electroless plating, or other suitable techniques. FIGS. 3-6 depict a few example systems that may be used to deposit a thin film upon a surface of an article.

FIG. 3 depicts an exemplary architecture of a deposition system 300 for performing aerosol deposition, according to some embodiments. System 300 may be used for applying various coatings to a component of processing equipment. System 300 may be used to apply coatings of many types of materials, including polymer coatings (e.g., high dielectric strength coatings), ceramic coatings (e.g., plasma resistant coatings), coatings including multiple components (such as a polymer phase and a ceramic phase), or other types of coatings. System 300 may be used to deposit precursor materials to react to form a coating on a surface of a body, e.g., may be used in aerosol-assisted chemical vapor deposition. System 300 includes a deposition chamber 302. The deposition chamber may include a stage 304 for mounting a component 306 to be coated (e.g., body 212 of FIG. 2, etc.). Ambient pressure in interior volume 303 of chamber 302 may be reduced via a vacuum system 308, coupled to inner volume 303 via exhaust port 309 defined in the body of chamber 302. Aerosol chamber 310 contains a coating powder for coating component 306, such as a polymer powder, a metal oxide powder, a mixture of powders, reactants to form a thin layer in chemical vapor deposition, etc. In some embodiments, material may be introduced in a different way, e.g., liquid may be co-sprayed with the carrier gas through nozzle 314. Aerosol chamber 310 is coupled to gas container 312. The coating material in aerosol chamber 310 may be in the form of a fine powder, e.g., may have particles ranging from a few μm to a few hundred μm in size. A carrier gas flows from gas container 312, through aerosol chamber 310 to interior volume 303. The carrier gas propels the coating powder through nozzle 314 for directing the coating powder onto component 306 to form a coating.

The component 306 may be a component used for semiconductor manufacturing. Component 306 may be a component of an etch reactor, a thermal reactor, a semiconductor processing chamber, or the like. Examples of possible components include a lid, a substrate support, process kit rings, a chamber liner, a nozzle, a showerhead, a wall, a base, a gas distribution plate, etc. Component 306 may be formed of a material such as aluminum, silicon, quartz, a metal oxide, a ceramic compound, a polymer, a composite, etc.

In some embodiments, the surface of component 306 may be polished to reduce a surface roughness of component 306. Reducing surface roughness may improve coating thickness and uniformity. In some embodiments, surface roughness is reduced until it is lower than the target thickness of a coating layer. In some embodiments, a surface of the body may be cleaned, e.g., have a metal oxide layer removed, prior to applying a bond layer. A metal oxide layer (or another surface contaminant) may be removed using any suitable technique, such as an acid wash, via sputtering, etc. In some embodiments, not all areas of component 306 are to be coated. Areas of component 306 that are not to be bonded (e.g., which are not to be adjacent to the bond, such as channels or voids inside the finished article) may be masked or shielded, or otherwise removed from the area accessed by the aerosol powder. In some embodiments, coating material may be removed from areas that are not to be coated after coating.

Component 306 may be mounted on stage 304 in deposition chamber 302 during deposition of a coating. Stage 304 may be a moveable stage (e.g., motorized stage) that can be moved in one, two, or three dimensions, and/or rotated in one or more dimensions, such that stage 304 can be moved to different positions to facilitate coating of component 306 with coating powder propelled from nozzle 314. For example, stage 304 may be moved to coat different portions or sides of component 306. Nozzle 314 may be selectively aimed at certain portions of component 306 from various angles and orientations.

In some embodiments, deposition chamber 302 may be evacuated using vacuum system 308. Providing a vacuum environment in inner volume 303 may facilitate application of the coating. For example, the coating powder propelled from nozzle 314 encounters less resistance as it travels to component 306 when inner volume 303 is under vacuum. Coating powder may impact component 306 more regularly, at a higher rate of speed, etc., which may facilitate adherence to component 306, facilitate formation of a coating, reduce wasted coating material, etc.

Gas container 312 holds a pressurized carrier gas. Pressurized carrier gasses that may be used include inert gasses, such as argon, nitrogen, krypton, etc. The pressurized carrier gas travels under pressure from gas container 312 to aerosol chamber 310. As the pressurized gas travels from aerosol chamber 310 to nozzle 314, the carrier gas propels some of the coating powder from aerosol chamber 310 toward nozzle 314.

In some embodiments, system 300 may be used to deposit a single material onto one or more surfaces of component 306. In some embodiments, system 300 may be used to deposit multiple materials onto component 306. In some embodiments, a polymer layer including multiple polymers may be deposited on component 306. In some embodiments, a ceramic layer including multiple ceramic materials may be deposited on component 306. In some embodiments, a material including a polymer phase and a ceramic phase may be deposited on component 306. In some embodiments, multiple coating precursors may be deposited. Multiple materials may be co-deposited by providing a mixture of powdered materials to aerosol chamber 310. In an alternate embodiment, two or more aerosol chambers may be coupled to pressurized gas and to nozzle 314, with each providing material to nozzle 314 separately. In an alternate embodiment, multiple nozzles may receive material from multiple aerosol chambers coupled to pressurized carrier gas. These embodiments may allow multiple materials to be deposited simultaneously. In some embodiments, different materials are to be deposited sequentially. In some embodiments, a reaction is allowed to proceed to generate a material for a coating. In some embodiments, a coated body may be cured (e.g., UV cured, oven cured, etc.) to facilitate a reaction to form a target coating.

As the carrier gas propelling a suspension of coating powder enters deposition chamber 302 from nozzle 314, the coating powder is propelled towards component 306. In one embodiment, the carrier gas is pressurized such that the coating powder is propelled towards component 306 at a rate between 150 m/s and 500 m/s. In some embodiments, particle size of the coating powder(s), and pressure(s) of carrier gas(ses) may be tuned for a target velocity distribution of coating powder.

In some embodiments, nozzle 314 is formed to be wear resistant. Due to movement of coating powder through nozzle 314 at high velocity, nozzle 314 can rapidly wear and degrade. Nozzle 314 may be formed in a shape and from a material such that wear is reduced.

In some embodiments, upon impacting component 306 particles of the coating powder fracture and deform from kinetic energy to produce a layer that adheres to component 306. As the application of coating powder continues, the particles become a coating or film by bonding to themselves. The coating on component 306 continues to grow by continuous collision of the particle of the coating powder on component 306. In some embodiments, particles mechanically collide with each other and with the substrate at a high speed under a vacuum to break into smaller pieces to form a dense layer, rather than melting. In some embodiments, crystal structure of particles of coating powder in aerosol chamber 310 is preserved through application to component 306. In some embodiments, melting of particles may occur when kinetic energy is converted to thermal energy. In some embodiments, aerosol deposition may be performed at room temperature, or between 15° C. and 35° C. In some embodiments, component 306 does not need to be heated and the aerosol application process may not significantly increase the temperature of component 306. Applications such as this may be used to coat assemblies that may be damaged in an environment of elevated temperature. For example, components formed of multiple parts affixed together with a bonding layer that melts at a low temperature may be damaged in a deposition process carried out at elevated temperatures. As a further example, components formed of multiple parts of different materials with different thermal expansion properties may be damaged as the parts expand at different rates, to different sizes, etc., during deposition. Such components may be less likely to be damaged by coating at ambient temperatures.

In some embodiments, aerosol deposition may be performed at an elevated temperature. In some embodiments, component 306 may be heated before or during aerosol deposition. Such heating may encourage melting of coating powder. In some embodiments, after deposition occurs, component 306 may be placed in an oven for heating of the component and coating material for a time. The temperature of component 306 and the coating may increase, such that the coating partially or fully melts. The coating may be allowed to flow over the surface of component 306, for example to improve uniformity of the coating, to allow the coating to reach new areas of the surface of component 306, etc.

In some embodiments, the coated component may be subjected to a post-coating process. For example, a ceramic coating may be polished or ground after application to component 306. Coated components may be subjected to other post-coating processes, such as thermal treatment. A thermal treatment in some embodiments forms a coating interface between the coating and the component. For example, a yttria (Y₂O₃) coating over an alumina (Al₂O₃) component can form a yittrium aluminum garnet (YAG) layer that aids in adhesion and provides further protection to the component. A barrier layer may reduce the occurrence of delamination, chipping, flaking, peeling, etc. Thermal treatment may also alter the chemical composition of the coating—a dual yttria/alumina coating may be converted to a YAG coating by thermal treatment, for example.

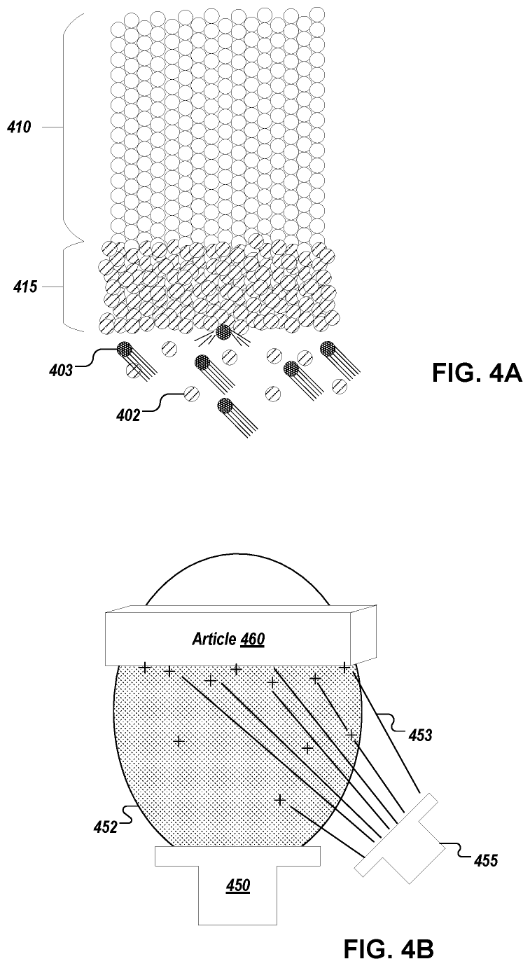

FIGS. 4A-B depict a mechanism and apparatus for performing deposition techniques utilizing energetic particles, according to some embodiments. FIG. 4A depicts a deposition mechanism applicable to a variety of deposition techniques utilizing energetic particles such as ion assisted deposition (IAD). Exemplary IAD methods include deposition processes which incorporate ion bombardment, such as evaporation (e.g., activated reactive evaporation (ARE)) and sputtering in the presence of ion bombardment to form coatings as described herein. Any of the IAD methods may be performed in the presence of a reactive gas species, such as O₂, N₂, halogens, etc.

As shown, a thin coating layer 415 is formed by an accumulation of deposition materials 402 in the presence of energetic particles 403 such as ions. The deposition materials 402 include atoms, ions, radicals, or their mixture. The energetic particles 403 may impinge and compact the thin final coating layer 415 as it is formed.

In one embodiment, IAD is utilized to form a thin coating layer 415, as previously described elsewhere herein. FIG. 4B depicts a schematic of an IAD deposition apparatus. As shown, a material source 450 provides a flux of deposition materials 452 for deposition on article 460 while an energetic particle source 455 provides a flux of the energetic particles 453, both of which impinge upon the article 460 throughout the IAD process. The energetic particle source 455 may be an oxygen or other ion source. The energetic particle source 455 may also provide other types of energetic particles such as inert radicals, neutron atoms, and nano-sized particles which come from particle generation sources (e.g., from plasma, reactive gases or from the material source that provide the deposition materials). IAD may utilize one or more plasmas or beams to provide the material and energetic ion sources. Reactive species may also be provided during deposition of the coating.

With IAD processes, the energetic particles 453 may be controlled by the energetic ion (or other particle) source 455 independently of other deposition parameters. According to the energy (e.g., velocity), density and incident angle of the energetic ion flux, composition, structure, crystalline orientation and grain size of the thin film protective layer may be manipulated. Additional parameters that may be adjusted are a temperature of the article during deposition as well as the duration of the deposition. The ion energy may be roughly categorized into low energy ion assist and high energy ion assist. The ions are projected with a higher velocity with high energy ion assist than with low energy ion assist. In general superior performance has been shown with high energy ion assist. Substrate (article) temperature during deposition may be roughly divided into low temperature (around 120-150° C. in one embodiment) and high temperature (around 270° C. in one embodiment).

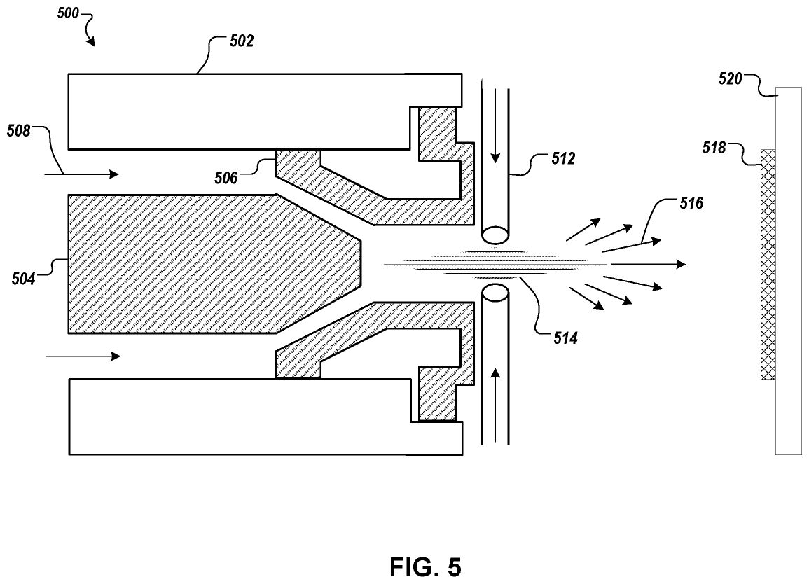

FIG. 5 depicts a schematic drawing of a plasma spray deposition apparatus 500 used for spray deposition techniques, according to some embodiments. The plasma spray apparatus 500 may include a casing 502 that encases a nozzle anode 506 and a cathode 504. The casing 502 permits gas flow 508 through the plasma spray device 500 and between the nozzle anode 506 and the cathode 504. An external power source may be used to apply a voltage potential between the nozzle anode 506 and the cathode 504. The voltage potential produces an arc between the nozzle anode 506 and the cathode 504 that ignites the gas flow 508 to produce a plasma gas. The ignited plasma gas flow 508 produces a high-velocity plasma plume 514 that is directed out of the nozzle anode 506 and toward an article 520.

The plasma spray apparatus 500 may be located in a chamber or atmospheric booth. In some embodiments, the gas flow 508 may be a gas or gas mixture including, but not limited to argon, nitrogen, hydrogen, helium, and combinations thereof. In some embodiments, wherein the spray system is used to perform slurry plasma spray, the plasma spray apparatus 500 may be equipped with one or more fluid lines 512 to deliver a slurry into the plasma plume 514. In some embodiments, a particle stream 516 is generated from plasma plume 514 and is propelled towards article 520. Upon impact with the article 520, the particle stream forms a coating 518.

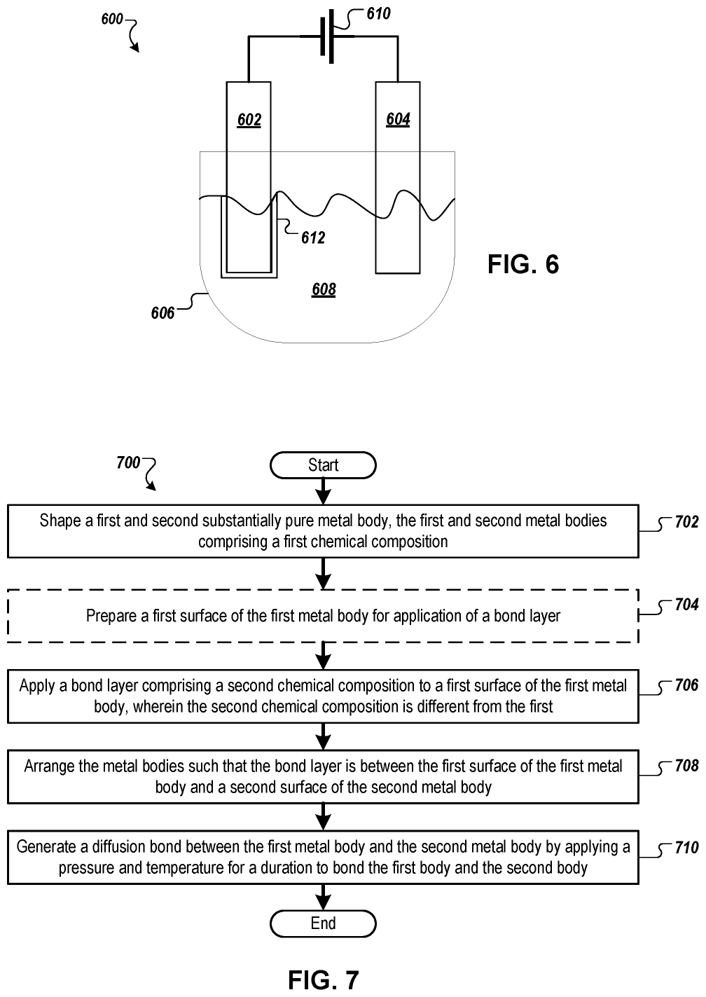

FIG. 6 illustrates a schematic drawing of an electroplating system 600 for applying a bonding layer coating, according to some embodiments. System 600 includes cathode 602 and anode 604, extending into vessel 606. Vessel 606 contains solution 608, in contact with cathode 602 and anode 604. The solution contains ions of a salt including the material of the anode 604. For example, if the anode is composed of copper, the solution may be of a soluble copper salt, such as copper sulphate. In some embodiments, the anode material may resist electrochemical oxidation, and may instead produce byproducts in solution.

DC power source 610 draws electrons from anode 604 and deposits electrons in cathode 602. Positively charged metal ions in solution 608 are drawn to the cathode. Metal atoms are deposited from solution 608 onto cathode 602 in a coating layer 612. In this way, a coating layer 612 of material from solution 608 is generated on the surface of cathode 602. In some embodiments, material of anode 604 replenishes ions in solution 608.

In some embodiments, the article to be manufactured by diffusion bonding is manufactured from a number of metal bodies, composed of substantially pure metal (e.g., at least 99.9% pure metal). Metal bodies may be machined or otherwise formed into a particular shape, e.g., channels or other complex geometries may be formed layer by layer by machining a number of metal bodies which are to be bonded. In some embodiments, surfaces of the metal bodies (e.g., surfaces to be bonded) are cleaned. Cleaning may include removing an oxide layer from the surfaces of the bodies (e.g., removing an oxide layer prior to applying a bond layer). Areas which are not to be bonded (or areas which are not to be plated with the bonding layer material) may be masked. Typical masking materials include tape, foil, lacquers, waxes, etc. The metal bodies may then be used as anodes in an electroplating system, such as system 600, to generate a thin layer of a bonding material on the unmasked portions of the bodies. In systems where the material of the anode is different than the plating material (e.g., the anode material does not replenish metal ions in solution), metal salt may be added to solution 608 as electroplating proceeds. The bodies may then be assembled, such that bodies to be bound have bonding material between them, and placed into a diffusion bonding system (e.g., system 200 of FIG. 2) to be bonded into a single article (e.g., single component of a manufacturing system).

In some embodiments, a bonding layer may be deposited using electroless plating. In some embodiments of an electroless plating process, an even layer of a nickel-phosphorous alloy is deposited on a surface of a solid substrate. Unlike electroplating, electroless plating does not typically pass a current through the material to be plated. In some applications, electroplating may deposit an uneven layer of material due to uneven current density, which may be caused by the shape of the cathode. Electroless plating may not be subject to such limitations.

Electroless plating includes submerging a body to be plated in an ion solution. The body may be machined, cleaned, masked, etc., before plating. The solution contains a source of nickel cations and a reducing agent. In one embodiment, the solution includes nickel sulfate and hypophosphite ions (e.g., sodium hypophosphite). A reaction occurs which yields solid nickel, elemental phosphorus, orthophosphate, protons, and molecular hydrogen. This reaction deposits a layer of a nickel phosphorus alloy on the surface of the body. Electroless plating may be catalyzed by nickel, and is suitable for coating a surface of a pure nickel body with a nickel alloy, generating a concentration gradient and driving atomic diffusion for a diffusion bonding process.

FIG. 7 is a flow diagram of a method 700 for manufacturing a diffusion-bonded article composed of substantially pure metal, according to some embodiments. At block 702, a first and second metal body are shaped. The metal bodies may be shaped from substantially pure metal. In some embodiments, the metal bodies are composed of pure nickel. In some embodiments, the first and second body a shaped from pure metal sheets. The composition of the first metal body and the second metal body are the same. Shaping the metal bodies may include, for example, machining channels, voids, or other geometries into one or more bodies.

At block 704, a first surface of the first metal body is prepared for application of a bond layer. The bond layer to be applied is of a second composition, different than the composition of the first metal body and the second metal body. The surface is to be bonded using diffusion bonding to the second metal body. Preparation of the first surface may include cleaning the surface. In some embodiments, contaminants are removed from the surface. Contaminants may include organic materials, inorganic materials, metal oxides, etc. In some embodiments, contaminants are removed using solvents, such as organic solvents, acids, bases, etc. In some embodiments, the surface is cleaned using sputtering or another method to remove material from a solid. Preparation of the first surface may include masking portions that are not to be bonded, e.g., masking channels or other machined features, masking sides or areas that are not to be in contact with a second metal body, etc.

At block 706, a bond layer is applied to the first surface of the first metal body. The bond layer comprises a second chemical composition, the second chemical composition being different than the first. The bond layer is applied to the first surface using any technique suitable for depositing a thin layer of a material onto a surface. The bond layer may be applied, for example, by performing physical vapor deposition, chemical vapor deposition, electroplating, electroless plating, atomic layer deposition, molecular layer deposition, ion assisted deposition, etc. In some embodiments, the bond layer may be less than 10 μm thick. In some embodiments, the bond layer may be less than 1 μm thick. In some embodiments, the bond layer may be less than 100 nm thick. In some embodiments, the bond layer may be about (e.g., +/−10%) 10 nm thick.

At block 708, the metal bodies (e.g., the first body and the second body) are arranged such that the bond layer is between the first surface of the first metal body and a second surface of the second metal body. In some embodiments, many metal bodies are bonded to generate a product. In some embodiments, many pure metal bodies may be stacked, such that coated bonding layers are interspersed between the pure metal bodies. In some embodiments, the article may be composed of alternating layers of pure metal bodies and bonding layers.

At block 710, a diffusion bonded article is generated by performing a diffusion bonding procedure on the metal bodies and bond layer. Diffusion bonding is accomplished by applying pressure and temperature to the metal bodies for a sufficient duration to bond the first body to the second body. Diffusion bonding systems and techniques are discussed in more detail in connection with FIG. 2.

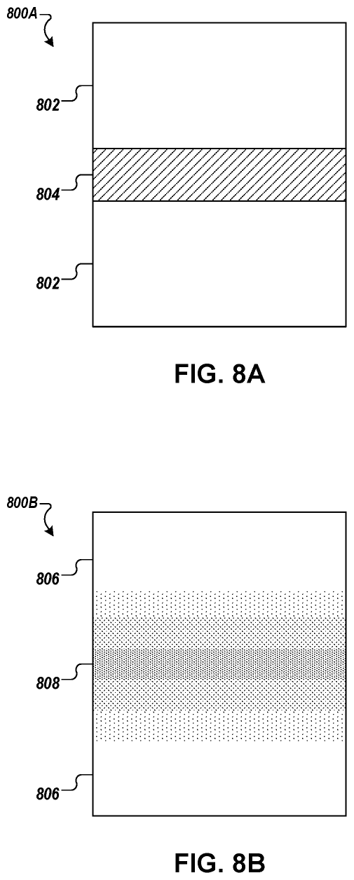

FIGS. 8A-B depict sectional views of exemplary articles 800A-B formed of substantially pure metal bodies 802 using diffusion bonding, according to some embodiments. Articles 800A-B may be any of various components, including manufacturing components, chamber components, etc. In some embodiments, articles 800A-B are showerheads. Substantially pure metal bodies 802 are composed of a pure metal (e.g., the same metal, 99.9% purity or greater). In some embodiments, metal bodies 802 are composed of nickel. Before diffusion bonding, one or more bodies 802 may have been shaped, machined, cleaned, have surface oxides removed, and/or been otherwise prepared for diffusion bonding (e.g., had surface polished to increase effective diffusion area, etc.). One or more bodies 802 may also have a thin layer of material added to drive diffusion bonding by creating a concentration gradient between pure metal bodies 802 and bonding layer 804.

Bonding layer 804 may be composed of several types of material. Bonding layer 804 may be composed of atoms that may replace atoms of the metal lattice of bodies 802. In some embodiments, materials such as gold and copper may replace nickel atoms in a lattice of a nickel metal body. In some embodiments, bonding layer 804 may be composed of atoms that sit interstitially within the lattice of metal bodies 802. Materials such as aluminum, boron, or titanium may sit interstitially in lattice of nickel atoms. In some embodiments, bonding layer 804 may be composed of an alloy of the material of bodies 802. A nickel-phosphorous alloy, such as that generated in electroless nickel plating, may generate a concentration gradient and may be used as bonding layer 804.

FIG. 8A is a representation of article 800A after deposition of bonding layer 804, prior to performance of diffusion bonding operations. Article 800A as depicted includes distinct layers—once diffusion bonded, however, atoms are exchanged between layers (e.g., from bodies 802 to bonding layer 804; from bonding layer 804 to bodies 802). The finished article may include gradual changes in composition, e.g., a composition or concentration gradient, rather than a distinct boundary.

FIG. 8B is a representation of article 800B after diffusion bonding operations are performed. Article 800B may not include distinct interfaces between metal bodies. Article 800B may include regions 806 of essentially the same material as bodies 802 (e.g., as the same region of the article before diffusion bonding). Atoms of the bodies 802 and bonding layer 804 may have exchanged, diffused, etc., and clear interfaces between layers may no longer be present. Instead, bonding layer 804 may be replaced with a transition region 808. In transition region 808, a spatial gradient of concentration exists. Near regions 806, transition region 808 may be composed of a composition that resembles that of pure metal bodies 802. The composition of the portion of article 800B farther from regions 806 of article 800B may more closely resemble the composition of bonding layer 804, e.g., may be an alloy of the material of bodies 802 and bonding layer 804, may have a higher concentration of material of bonding layer 804 than surrounding regions, etc.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular embodiments may vary from these exemplary details and still be contemplated to be within the scope of the present disclosure.

Reference throughout this specification to “one embodiment” or “an embodiment” indicates that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method, comprising:
applying a bond layer comprising a first chemical composition to a first surface of a first metal body comprising a second chemical composition, wherein the second chemical composition is different from the first chemical composition;
disposing a second metal body having the second chemical composition against the first metal body such that the bond layer is between the first surface of the first metal body and a second surface of the second metal body, wherein the first metal body and the second metal body are resistant to diffusion bonding, and wherein the bond layer facilitates diffusion bonding of the second metal body to the first metal body;
heating the first metal body and the second metal body;
applying pressure to press the second metal body against the first metal body; and
generating a diffusion bond between the second metal body and the first metal body responsive to the heating and the applying of pressure for a duration.

2. The method of claim 1, wherein a purity of the first metal body and a purity of the second metal body are 99.99% or higher.

3. The method of claim 1, wherein the bond layer has a thickness of 5 μm or less.

4. The method of claim 1, wherein the bond layer has a thickness of 100 nm or less.

5. The method of claim 1, wherein at least the first surface of the first metal body and the second surface of the second metal body consist of substantially pure nickel.

6. The method of claim 1, wherein applying the bond layer comprises at least one of:
performing physical vapor deposition;
performing chemical vapor deposition;
performing electroplating;
performing electroless plating;
performing atomic layer deposition; or
performing ion assisted deposition.

7. The method of claim 1, further comprising preparing the first surface of the first metal body prior to application of the bond layer, wherein preparing the first surface includes one or more of:
removing organic surface contaminants;
removing inorganic surface contaminants;
polishing the first surface; or
removing a layer of metal oxide from the first surface.

8. The method of claim 1, further comprising masking areas of the first metal body prior to applying the bond layer, wherein masked areas are not to be adjacent to the diffusion bond.

9. The method of claim 1, wherein the first metal body and the second metal body are heated to a temperature that is between 50% and 90% of an absolute melting temperature of the first chemical composition.

10. The method of claim 1, further comprising shaping the first metal body prior to applying the bond layer.

11. A chamber component for a processing chamber, comprising:
a first substantially pure metal body, comprising a first chemical composition;
a second substantially pure metal body, comprising the first chemical composition, wherein the first chemical composition is resistant to diffusion bonding; and
a diffusion bond between a first surface of the first metal body and a second surface of the second metal body, wherein the diffusion bond comprises a spatial gradient of the first chemical composition and a second chemical composition of a bond layer from the first metal body through the bond layer to the second metal body.

12. The chamber component of claim 11, wherein a purity of the first metal body is 99.99% or higher.

13. The chamber component of claim 11, wherein the first chemical composition consists of pure nickel.

14. The chamber component of claim 11, wherein the second chemical composition is an alloy of nickel.

15. The chamber component of claim 14, wherein the second chemical composition is a nickel-phosphorous alloy.

16. A processing chamber, comprising a showerhead, the showerhead comprising:
a first substantially pure metal body, comprising a first chemical composition;
a second substantially pure metal body, comprising the first chemical composition, wherein the first chemical composition is resistant to diffusion bonding; and
a diffusion bond between a first surface of the first metal body and a second surface of the second metal body, wherein the diffusion bond comprises a spatial gradient of the first chemical composition and a second chemical composition of a bond layer from the first metal body through the bond layer to the second metal body.

17. The processing chamber of claim 16, wherein a purity of the first metal body is 99.99% or higher.

18. The processing chamber of claim 16, wherein the first chemical composition consists of substantially pure nickel.

19. The processing chamber of claim 16, wherein the second chemical composition comprises an alloy of the first chemical composition.

20. The processing chamber of claim 19, wherein the first chemical composition comprises substantially pure nickel, and wherein the second chemical composition comprises a nickel-phosphorous alloy.
